(19) United States
(12) Patent Application Publication
(10) Pub. No.: US 2007/0141388 A1
(43) Pub. Date: Jun. 21, 2007

(54) Electroluminescent device containing a butadiene derivative

(75) Inventors: Margaret J. Helber, Webster, NY (US); Zbyslaw R. Owczarczyk, Webster, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/305,424

(22) Filed: Dec. 16, 2005

(51) Int. Cl. H01L 51/54

(52) U.S. Cl. 428/690; 428/917; 313/504; 313/506; 313/112; 257/102; 257/103; 257/E51.049; 257/E51.051; 257/98

(57) ABSTRACT

An OLED device comprises a cathode, an anode and a light-emitting layer therebetween, wherein the light-emitting layer comprises a host containing an anthracene nucleus and a light-emitting material comprising a 1,3-butadiene nucleus, wherein the butadiene nucleus is substituted in the 1 and 4 positions with independently selected aromatic groups, and wherein at least one of said aromatic groups is further substituted with an amino group, and wherein said amino group is further substituted with two independently selected aryl or heteroaryl groups.

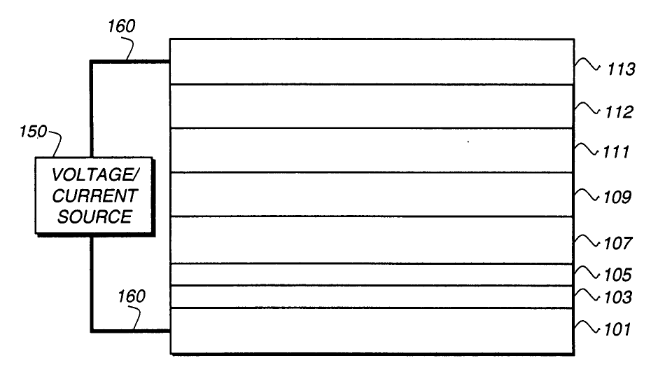

### FIELD OF THE INVENTION

This invention relates to an electroluminescent (EL) device comprising a light-emitting layer comprising a butadiene derivative and a host containing an anthracene nucleus that can provide desirable electroluminescent properties.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, 30, 322, (1969); and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often greater than 100V.

More recent organic EL devices include an organic EL element consisting of extremely thin layers (e.g. <1.0 μm) between the anode and the cathode. Herein, the term “organic EL element” encompasses the layers between the anode and cathode. Reducing the thickness lowered the resistance of the organic layers and has enabled devices that operate at much lower voltage. In a basic two-layer EL device structure, described first in U.S. Pat. No. 4,356,429, one organic layer of the EL element adjacent to the anode is specifically chosen to transport holes, and therefore is referred to as the hole-transporting layer, and the other organic layer is specifically chosen to transport electrons and is referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by C. Tang et al. (J. Applied Physics, Vol. 65, 3610 (1989)). The light-emitting layer commonly consists of a host material doped with a guest material, otherwise known as a dopant. Still further, there has been proposed in U.S. Pat. No. 4,769,292 a four-layer EL element comprising a hole injecting layer (HIL), a hole-transporting layer (HTL), a light-emitting layer (LEL) and an electron-transporting/injecting layer (ETL). These structures have resulted in improved device efficiency.

Since these early inventions, further improvements in device materials have resulted in improved performance in attributes such as color, stability, luminance efficiency and manufacturability, e.g., as disclosed in U.S. Pat. No. 5,061,569, U.S. Pat. No. 5,409,783, U.S. Pat. No. 5,554,450, U.S. Pat. No. 5,593,788, U.S. Pat. No. 5,683,823, U.S. Pat. No. 5,908,581, U.S. Pat. No. 5,928,802, U.S. Pat. No. 6,020,078, and U.S. Pat. No. 6,208,077, amongst others.

Notwithstanding these developments, there are continuing needs for organic EL device components, such as light-emitting materials, sometimes referred to as dopants, that will provide high luminance efficiencies combined with high color purity and long lifetimes. In particular, there is a need to be able to adjust the emission wavelength of the light-emitting material for various applications. For example, in addition to the need for blue, green, and red light-emitting materials there is a need for blue-green, yellow and orange light-emitting materials in order to formulate white-light emitting electroluminescent devices. For example, a device can emit white light by emitting a combination of colors, such as blue-green light and red light or a combination of blue light and yellow light.

The preferred spectrum and precise color of a white EL device will depend on the application for which it is intended. For example, if a particular application requires light that is to be perceived as white without subsequent processing that alters the color perceived by a viewer, it is desirable that the light emitted by the EL device have 1931 Commission International d'Eclairage (CIE) chromaticity coordinates, (CIEx, CIEy), of about (0.33, 0.33). For other applications, particularly applications in which the light emitted by the EL device is subjected to further processing that alters its perceived color, it can be satisfactory or even desirable for the light that is emitted by the EL device to be off-white, for example bluish white, greenish white, yellowish white, or reddish white.

White EL devices can be used with color filters in full-color display devices. They can also be used with color filters in other multicolor or functional-color display devices. White EL devices for use in such display devices are easy to manufacture, and they produce reliable white light in each pixel of the displays. Although the OLEDs are referred to as white, they can appear white or off-white, for this application, the CIE coordinates of the light emitted by the OLED are less important than the requirement that the spectral components passed by each of the color filters be present with sufficient intensity in that light. Thus there is a need for new materials that provide high luminance intensity for use in white OLED devices. The devices must also have good stability in long-term operation. That is, as the devices are operated for extended periods of time, the luminance of the devices should decrease as little as possible.

In particular, there is a need to be able to adjust the emission wavelength of the light-emitting material for various applications. For example, efficient emissive blue and blue-green dopants continue to be of significant interest. Emissive blue dopants containing the perylene nucleus (S. A. Van Slyke, U.S. Pat. No. 5,151,629) have been employed commercially for a number of years. For example, a perylene derivative, (2,5,8,11)-tetra-tert-butylperylene (TBP), has been used commercially in part because of its desirable CIE color coordinates (JP 09-241629). In addition to perylenes, emissive blue dopants containing one or more stilbene structures have been described (U.S. Pat. No. 5,121,029, EP 373,582, U.S. Pat. No. 2,651,237, U.S. Pat. No. 2,670,121, U.S. Pat. No. 2,774,654, U.S. Pat. No. 2,777,179, U.S. Pat. No. 2,809,473). JP 2004/196716 describes stilbene compounds that have a trisubstituted double bond.

Commonly assigned Ser. No. 10/977,839, filed Oct. 29, 2004 entitled Organic Element for Electroluminescent Devices by Margaret J. Helber, et al., which is incorporated herein by reference, describes additional useful blue and blue-green light-emitting materials.

S. Pfeiffer and co-workers (SPIE, 3476, 258 (1998)) report vinylene-bridged triphenylamine dimers as emitting materials, used in combination with the host material TAZ (3-(4-biphenyl)-4-phenyl-5-(4-t-butylphenyl)-1,2,4-triazole), in OLED devices. However, this combination of materials is not as efficient as desired.

It is a problem to be solved to provide light-emitting components for an EL device that exhibits good luminous yield with desirable color coordinates, particularly in the blue or blue-green region.

### SUMMARY OF THE INVENTION

The invention provides an OLED device comprising a cathode, an anode and a light-emitting layer therebetween, wherein the light-emitting layer comprises a host containing an anthracene nucleus and a light-emitting material comprising a 1,3-butadiene nucleus, wherein the butadiene nucleus is substituted in the 1 and 4 positions with independently selected aromatic groups, and wherein at least one of said aromatic groups is further substituted with an amino group, and wherein said amino group is further substituted with two independently selected aryl or heteroaryl groups. The device exhibits good luminous yield with desirable color coordinates, particularly in the blue or blue-green region.

### BRIEF DESCRIPTION OF THE DRAWINGS

The Figure shows a schematic cross-sectional view of one embodiment of the present invention including a light-emitting layer.

### DETAILED DESCRIPTION OF THE INVENTION

The invention is generally described above. The invention provides for an OLED device having a light-emitting layer (LEL) between a cathode and an anode. The light-emitting layer includes a host material that has at least one anthracene nucleus. Desirably, the anthracene is substituted in the 9- and 10-positions with two independently selected aromatic groups. Examples of aromatic groups include phenyl groups, naphthyl groups, biphenyl groups, and pyridyl groups.

The LEL also includes a light-emitting material that has a 1,3-butadiene nucleus. The butadiene nucleus is substituted in the 1 and 4 positions with independently selected aromatic groups. Examples of aromatic groups include phenyl groups, naphthyl groups, anthranyl groups, phenanthryl groups, and quinolyl groups. At least one of the aromatic groups is further substituted with an amino group. The amino group is further substituted with two independently selected aryl or heteroaryl groups, such as phenyl groups, naphthyl groups, or pyridyl groups.

The butadiene is substituted in both the 1 and 4 positions with independently selected aromatic groups and in one embodiment each aromatic group is further substituted with an amino group. Each of these amino groups is further substituted with two independently selected aryl or heteroaryl groups, such as a phenyl group, a naphthyl group, or a pyridyl group. Desirably, the two amino groups are conjugated to one another.

In one embodiment, suitable substituents on the butadiene nucleus are chosen so that the butadiene nucleus is in the trans form. This may lead to higher fluorescence quantum efficiency relative to the cis form and thus provide a more efficient light-emitting material for the OLED device.

In one embodiment, the light-emitting material is represented by Formula (1).

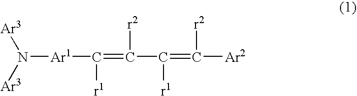

In Formula (1), Ar¹ represents a divalent aromatic group, such as, for example a 1,4-phenylene group, 1,3-phenylene group, 1,4-naphthylene group, 2,6-naphthylene group, quinoline-5,8-diyl group, or a 4,4′-biphenylene group, which may be further substituted.

Illustrative examples of Ar¹ are also shown below.

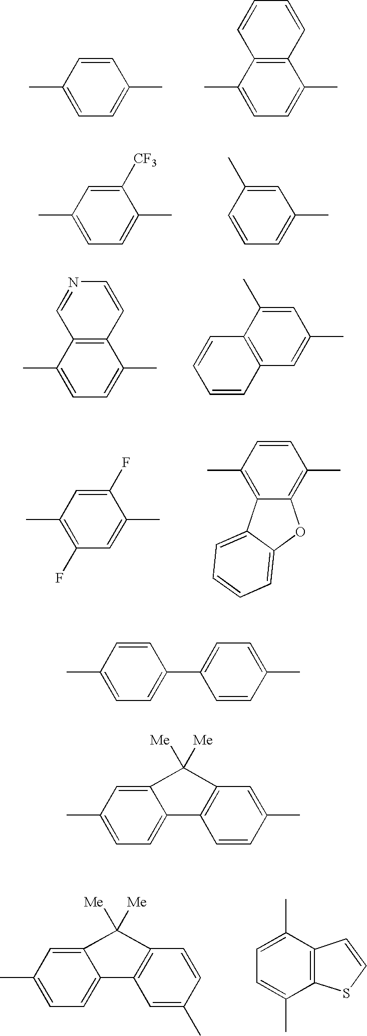

Ar² represents an aromatic group such as a phenyl group, a naphthyl group, or a pyridyl group. Illustrative examples are also listed below.

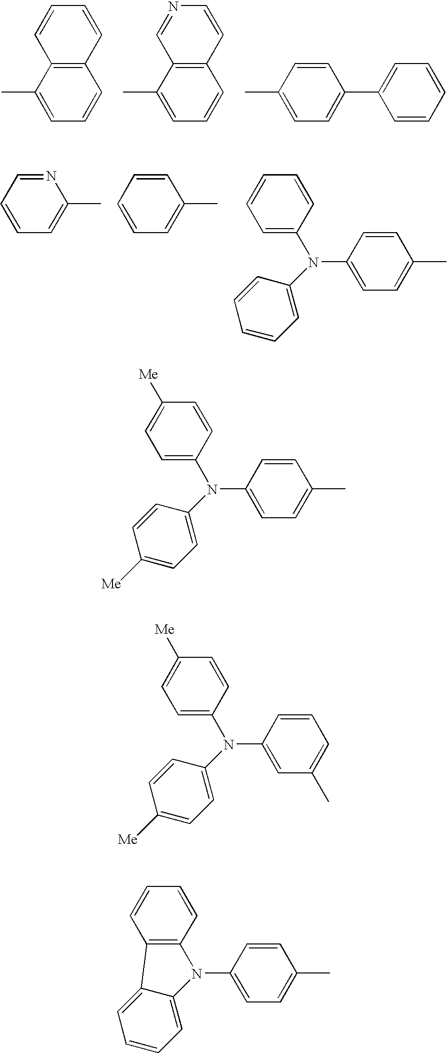

Each Ar³ may be the same or different and each represents an independently selected aromatic group. The two Ar³ groups may combine to form a ring group, such as a carbazole ring group. Examples of Ar³ groups include naphthyl groups, anthranyl groups, phenanthryl groups, biphenyl groups, pyridyl groups, furyl groups, quinolyl groups, isoquinolyl groups and thienyl groups.

In one embodiment, Ar¹, Ar² and each Ar³ represent carbocyclic aromatic groups. In another embodiment, Ar¹ represents a biphenylene group.

In an additional embodiment, Ar² is further substituted with a N(Ar⁴)(Ar⁴) group, wherein each Ar⁴ may be the same or different and each represents an independently selected aromatic group, for example a phenyl group or a naphthyl group. The two Ar⁴ groups may combine to form a ring group, such as a carbazole ring group.

In Formula (1), each r¹ may be the same or different and each r² may be the same or different and each represents hydrogen or a substituent, such as a methyl group, a trifluoromethyl group, or a phenyl group. In one suitable embodiment, at least one r¹ represents hydrogen and at least one r² represents hydrogen. In one desirable embodiment, each r¹ and each r² represents hydrogen.

In another aspect of the invention, the light-emitting material is represented by Formula (2).

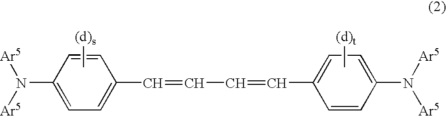

In Formula (2), each Ar⁵ may be the same or different and each represents an independently selected aromatic group, such as a phenyl group, a naphthyl group, an anthranyl group or a phenanthryl group. Two adjacent Ar⁵ groups may combine to form a ring group, such as a carbazole ring group.

In Formula (2), each d represents an independently selected substituent, such as a methyl group, a trifluoromethyl group, or a fluoro substituent. Two adjacent d groups may combine to form a ring group, for example, a fused benzene ring group.

In the Formula, s is 0-4 and t is 0-4. In one desirable embodiment s and t are 0.

Compounds of Formula (1) can be prepared by literature procedures including those described by S. Pfeiffer and co-workers (SPIE, 3476, 258 (1998)). For example, three illustrative routes to compounds of Formula (1) are shown in equations A, B, and C, which employ the Wittig-Horner reaction. Reacting a suitable phosphonate ester and aldehyde yields a compound such as Cpd-A, Cpd-B, or Cpd-C as shown below.

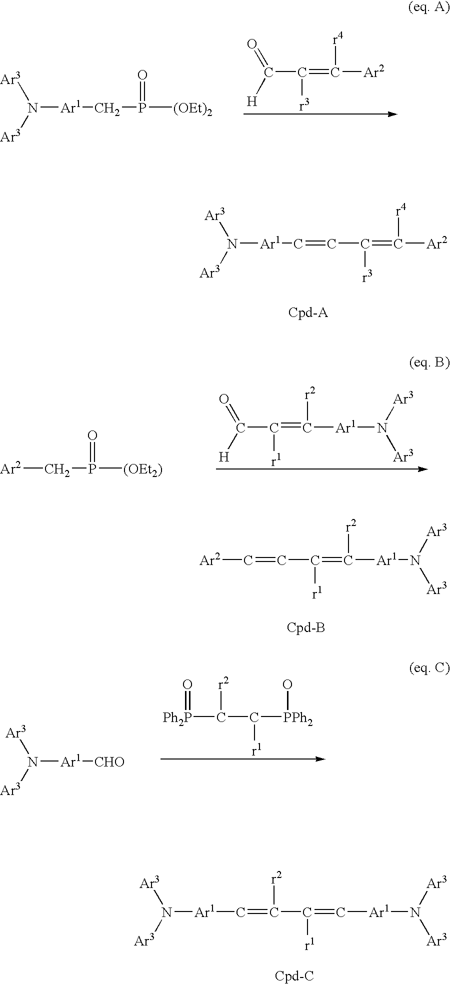

Illustrative examples of materials of Formula (1) are listed below.

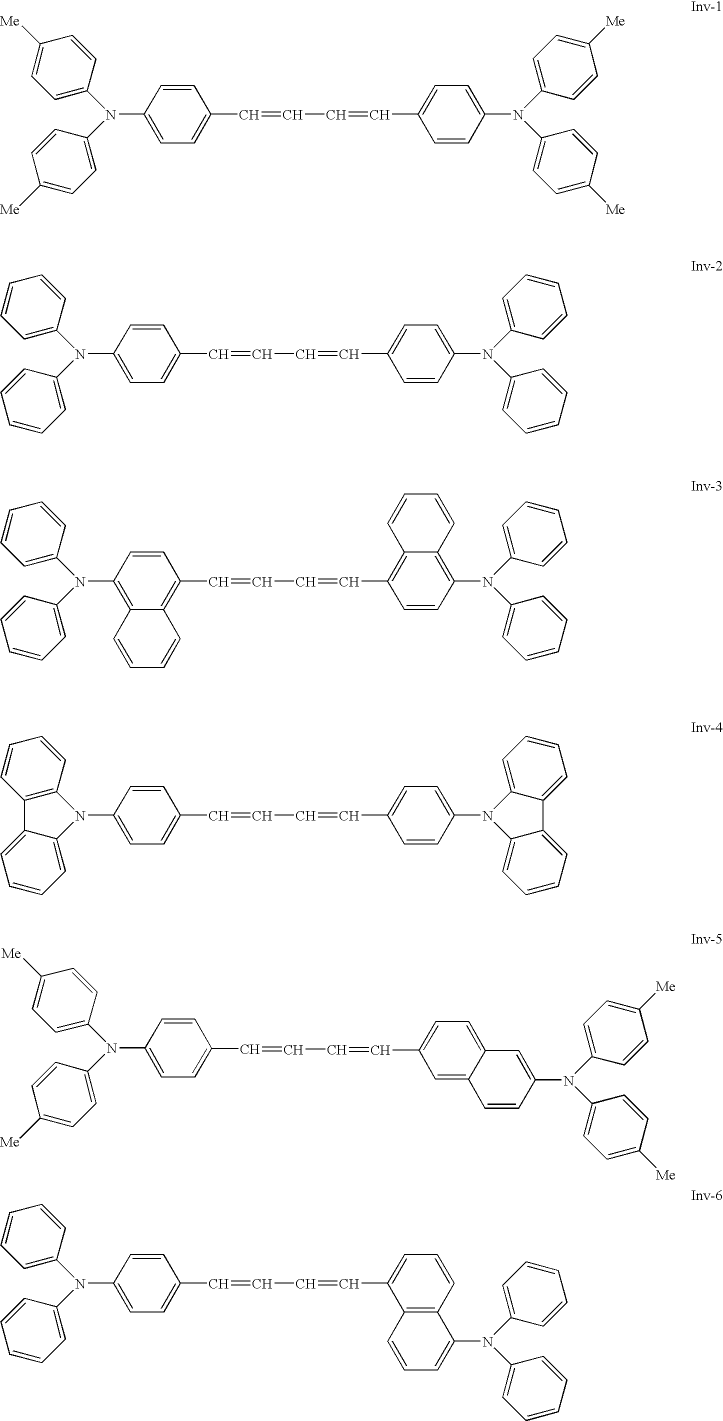

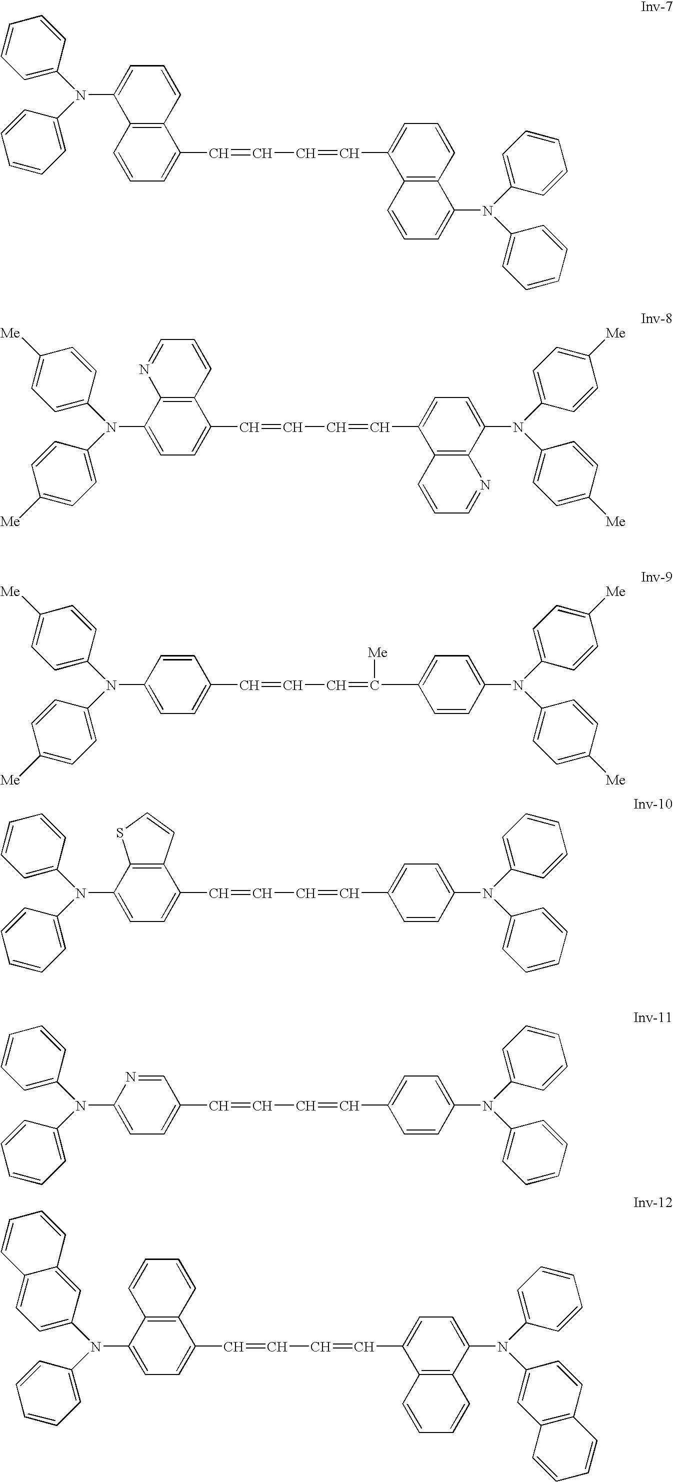

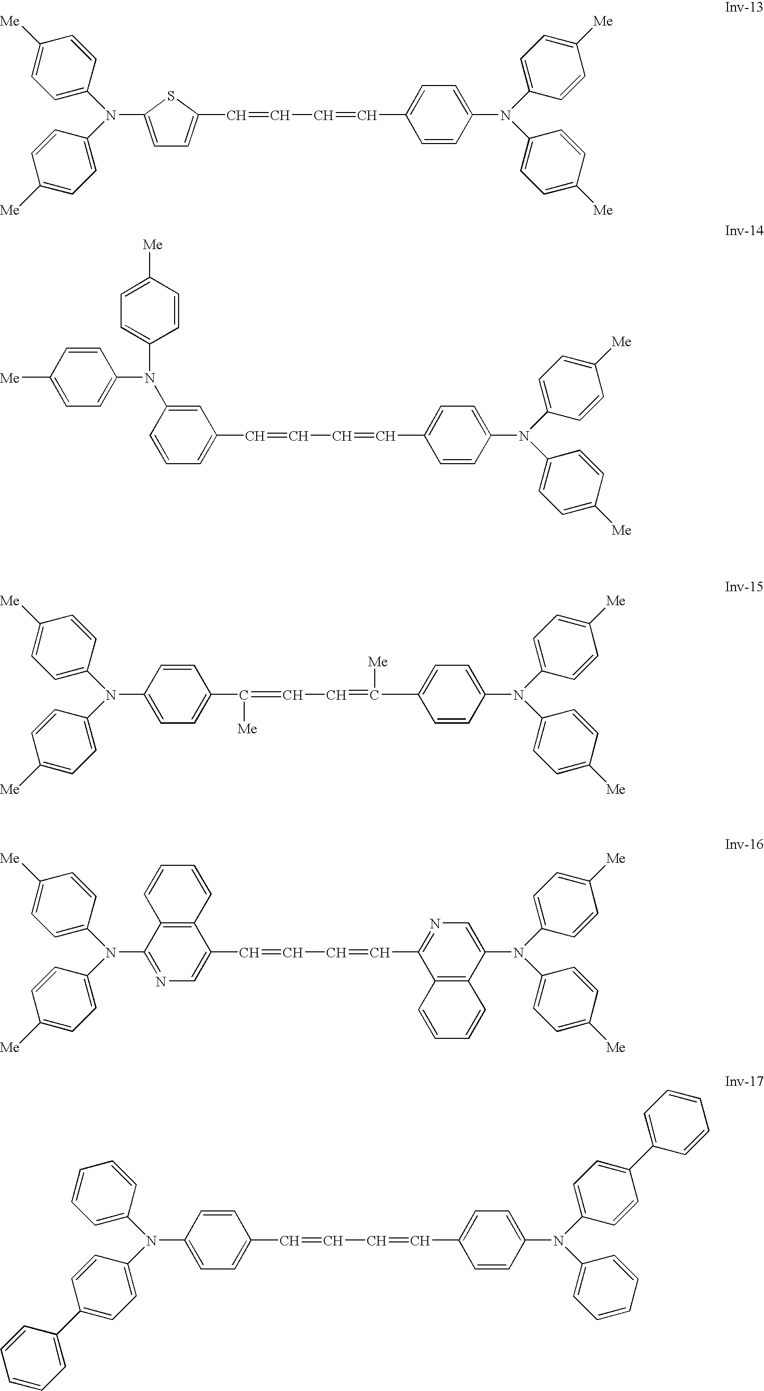

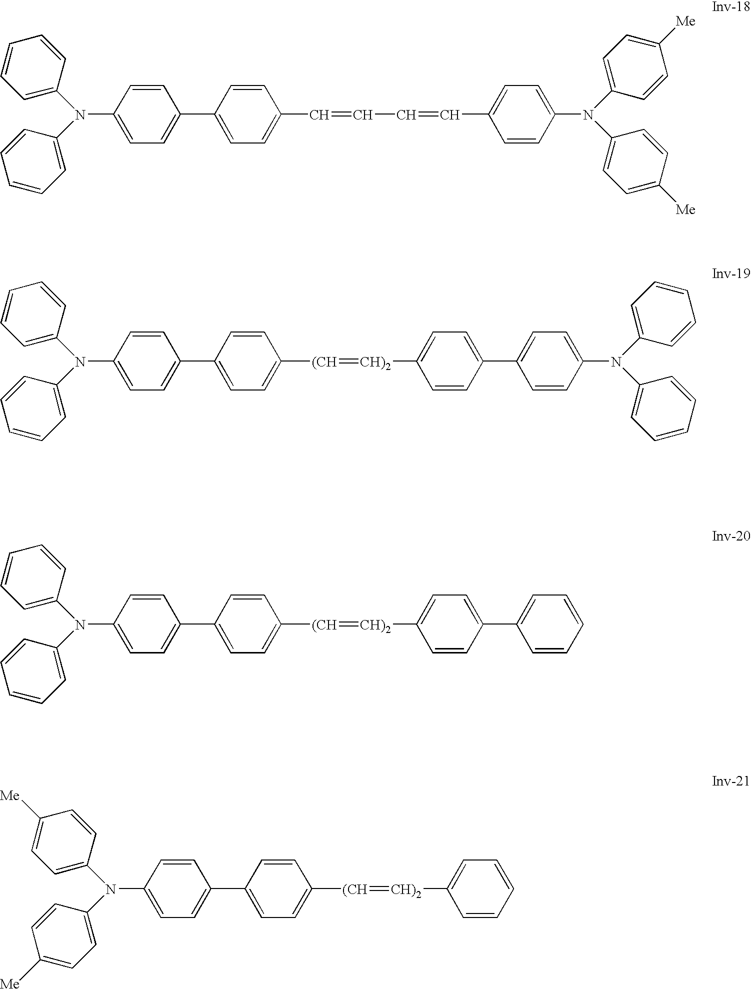

The light-emitting layer includes a host material that has at least one anthracene nucleus. In one embodiment the host is an anthracene of Formula (3).

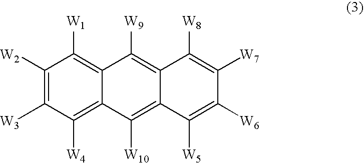

In Formula (3), W₁-W₁₀ independently represent hydrogen or an independently selected substituent, provided that two adjacent substituents can combine to form a ring. In one aspect of the invention, W₉ and W₁₀ represent independently selected naphthyl groups or biphenyl groups. For example, W₉ and W₁₀ may represent such groups as 1-naphthyl, 2-naphthyl, 4-biphenyl, and 3-biphenyl. In another desirable embodiment, at least one of W₉ and W₁₀ represents an anthracene group. In a further aspect of the invention, W₉ and W₁₀ represent independently selected naphthyl groups or biphenyl groups and W₇ represents an aromatic group, such as a phenyl group or a naphthyl group. In one embodiment the anthracene compound is selected from the group consisting of 9,10-di-(2-naphthyl)anthracene, 2-t-butyl-9,10-di-(2-naphthyl)anthracene, 9-(2-naphthyl)-10-(4-biphenyl)anthracene, and 9,10-di-(2-naphthyl)-2-phenylanthracene.

The anthracene host can be present as the only host or it can be mixed with other host materials. The anthracene host may also be mixed with other nonanthracene host materials, such as Alq.

Illustrative examples of useful anthracene hosts are shown below.

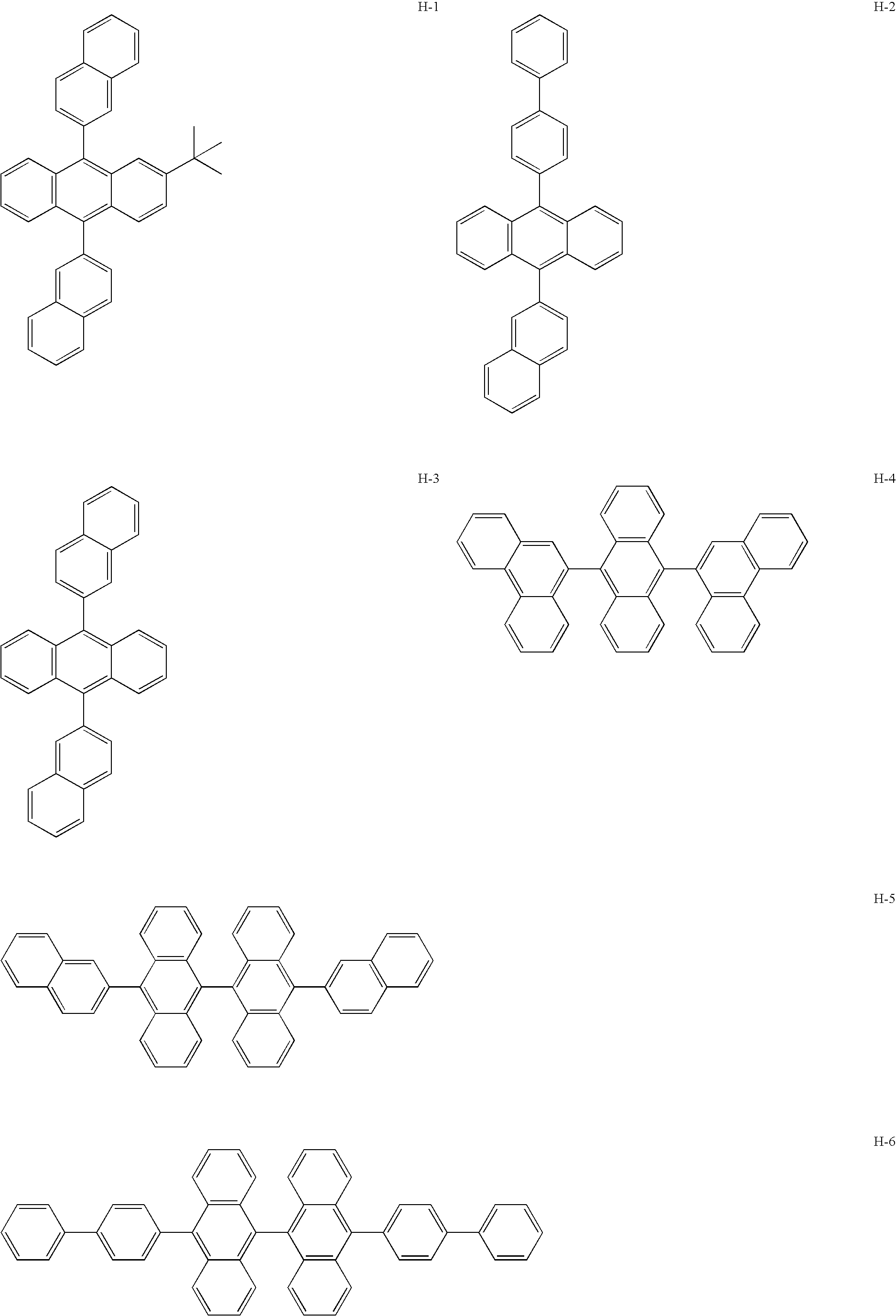

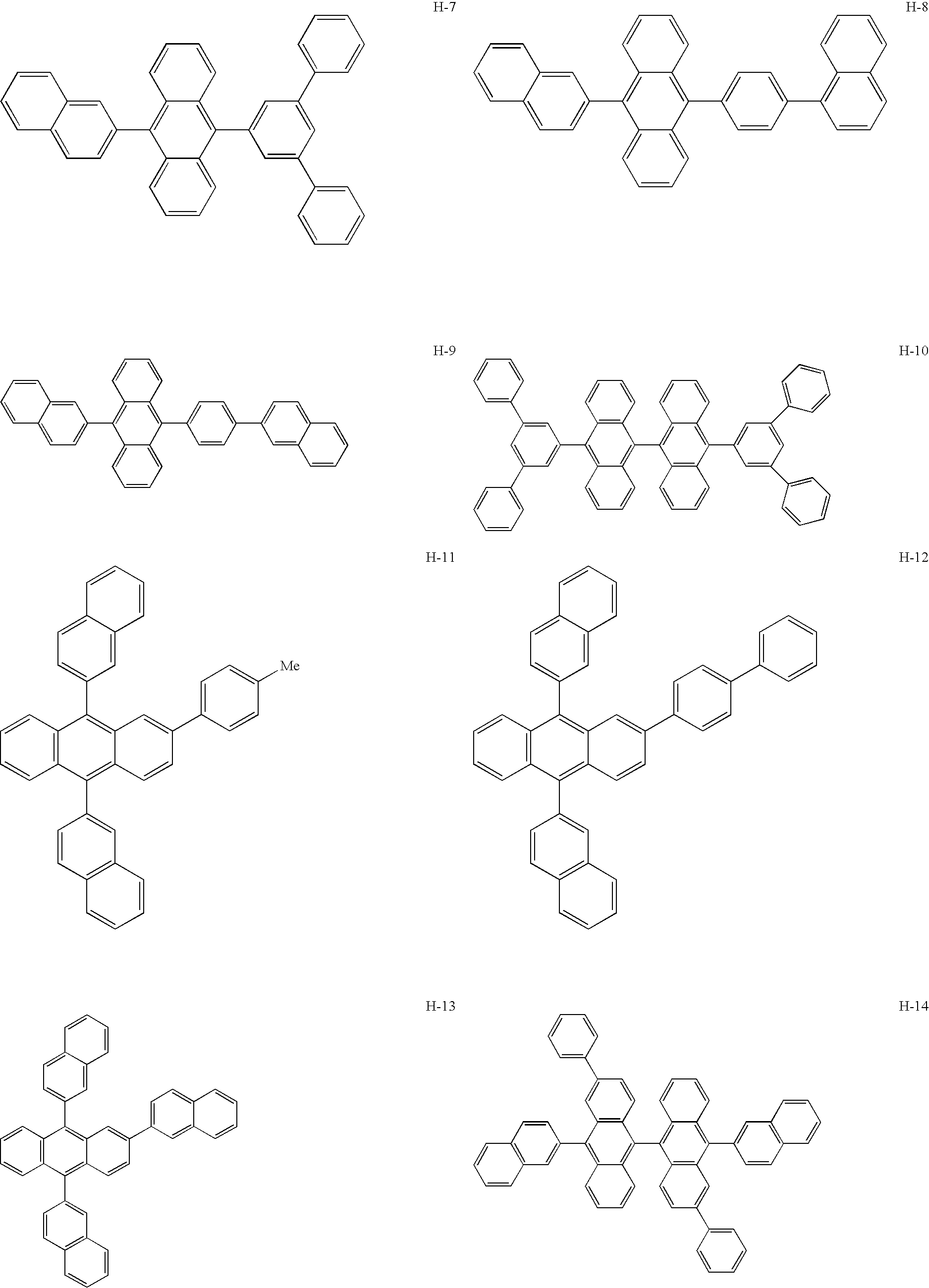

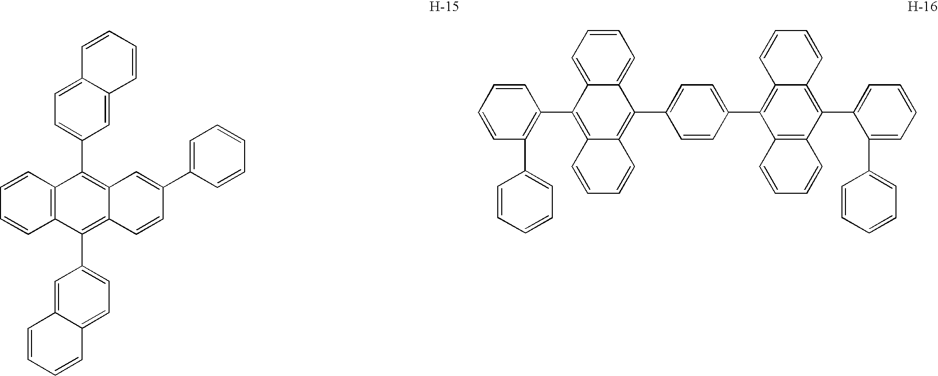

In one embodiment of the invention, the device includes a second light-emitting layer, including at least one host material and at least one light-emitting material. Suitably, the host in the second layer may be an anthracene type host or a non-anthracene host, such as Alq.

In a further aspect of the invention, the light-emitting material of Formula (1) emits blue or blue-green light and at least one light-emitting material, in the second light-emitting layer, emits yellow light. Blue light is generally defined as having a wavelength range in the visible region of the electromagnetic spectrum of 450-480 nm, blue-green 480-510 nm, green 510-550, green-yellow 550-570 nm, yellow 570-590 nm, orange 590-630 nm and red 630-700 nm, as defined by Dr. R. W. G. Hunt in The Reproduction of Colour in Photography, Printing & Television, 4th Edition 1987, Fountain Press, page 4. Suitably, in this aspect, the inventive device emits white light or light that can be corrected by means of filtration to give white light.

Examples of useful yellow dopants include 5,6,11,12-tetraphenylnaphthacene (rubrene); 6,11-diphenyl-5,12-bis(4-(6-methyl-benzothiazol-2-yl)phenyl)naphthacene; 5,6,11,12-tetra(2-naphthyl)naphthacene; and

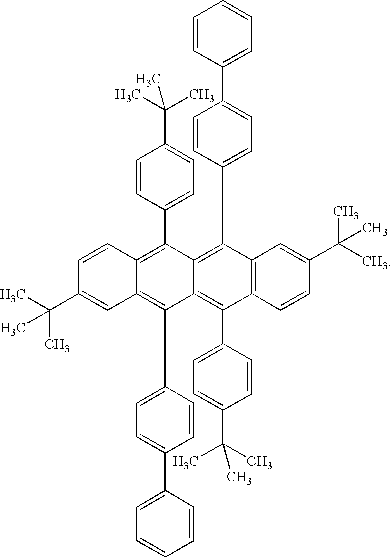

Examples of yellow light-emitting materials also include compounds represented by the following formula:

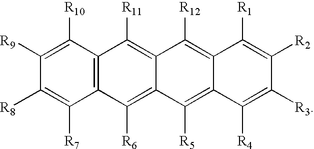

R₁, R₂, R₃, R₄, R₅, R₆, R₇, R₈, R₉, R₁₀, R₁₁, and R₁₂ are independently selected as hydrogen or substituent groups. Such substituent groups may join to form further fused rings. In one suitable embodiment, R₁, R₃, R₄, R₇, R₉, R₁₀, represent hydrogen; R₂ and R₈ represent hydrogen or independently selected alkyl groups; R₅, R₆, R₁₁, and R₁₂ represent independently selected aryl groups.

Unless otherwise specifically stated, use of the term “substituted” or “substituent” means any group or atom other than hydrogen. Additionally, unless otherwise specifically stated, when a compound with a substitutable hydrogen is identified or the term “group” is used, it is intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example, halogen, such as chloro, bromo or fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy) propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonyl amino, p-tolylcarbonylamino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur or phosphorous, such as pyridyl, thienyl, furyl, azolyl, thiazolyl, oxazolyl, imidazolyl, pyrazolyl, pyrazinyl, pyrimidinyl, pyrolidinonyl, quinolinyl, isoquinolinyl, 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

For the purpose of this invention, also included in the definition of a heterocyclic ring are those rings that include coordinate or dative bonds. The definition of a coordinate bond can be found in Grant & Hackh 's Chemical Dictionary, page 91. In essence, a coordinate bond is formed when electron rich atoms such as O or N, donate a pair of electrons to electron deficient atoms such as A1 or B.

It is well within the skill of the art to determine whether a particular group is electron donating or electron accepting. The most common measure of electron donating and accepting properties is in terms of Hammett σ values. Hydrogen has a Hammett σ value of zero, while electron donating groups have negative Hammett σ values and electron accepting groups have positive Hammett σ values. Lange's handbook of Chemistry, 12^{th} Ed., McGraw Hill, 1979, Table 3-12, pp. 3-134 to 3-138, here incorporated by reference, lists Hammett σ values for a large number of commonly encountered groups. Hammett σ values are assigned based on phenyl ring substitution, but they provide a practical guide for qualitatively selecting electron donating and accepting groups.

Suitable electron donating groups may be selected from —R′, —OR′, and —NR′(R″) where R′ is a hydrocarbon containing up to 6 carbon atoms and R″ is hydrogen or R′. Specific examples of electron donating groups include methyl, ethyl, phenyl, methoxy, ethoxy, phenoxy, —N(CH₃)₂, —N(CH₂CH₃)₂, —NHCH₃, —N(C₆H₅)₂, —N(CH₃)(C₆H₅), and —NHC₆H₅.

Suitable electron accepting groups may be selected from the group consisting of cyano, α-haloalkyl, α-haloalkoxy, amido, sulfonyl, carbonyl, carbonyloxy and oxycarbonyl substituents containing up to 10 carbon atoms. Specific examples include —CN, —F, —CF₃, —OCF₃, —CONHC₆H₅, —SO₂C₆H₅, —COC₆H₅, —CO₂C₆H₅, and —OCOC₆H₅.

General Device Architecture

The present invention can be employed in many OLED device configurations using small molecule materials, oligomeric materials, polymeric materials, or combinations thereof. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

A typical structure, especially useful for of a small molecule device, is shown in the Figure and is comprised of a substrate 101, an anode 103, a hole-injecting layer 105, a hole-transporting layer 107, a light-emitting layer 109, an electron-transporting layer 111, an electron-injecting layer 112, and a cathode 113. These layers are described in detail below. Note that the substrate may alternatively be located adjacent to the cathode, or the substrate may actually constitute the anode or cathode. The organic layers between the anode and cathode are conveniently referred to as the organic EL element. Also, the total combined thickness of the organic layers is desirably less than 500 nm.

The anode and cathode of the OLED are connected to a voltage/current source 150 through electrical conductors 160. The OLED is operated by applying a potential between the anode and cathode such that the anode is at a more positive potential than the cathode. Holes are injected into the organic EL element from the anode and electrons are injected into the organic EL element at the cathode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

The OLED device of this invention is typically provided over a supporting substrate 101 where either the cathode or anode can be in contact with the substrate. The substrate can be a complex structure comprising multiple layers of materials. This is typically the case for active matrix substrates wherein TFTs are provided below the OLED layers. It is still necessary that the substrate, at least in the emissive pixilated areas, be comprised of largely transparent materials. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support can be light transmissive, light absorbing or light reflective. Substrates for use in this case include, but are not limited to, glass, plastic, semiconductor materials, silicon, ceramics, and circuit board materials. It is necessary to provide in these device configurations a light-transparent top electrode.

Anode

When the desired electroluminescent light emission (EL) is viewed through anode, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode, the transmissive characteristics of the anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injecting Layer (HIL)

While not always necessary, it is often useful that a hole-injecting layer 105 be provided between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino]triphenylamine). Alternative hole-injecting materials reportedly useful in organic EL devices are described in EP0891121 and EP1029909.

Additional useful hole-injecting materials are described in U.S. Pat. No. 6,720,573. For example, the material below may be useful for such purposes. 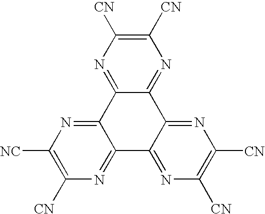
Hole-Transporting Layer (HTL)

The hole-transporting layer 107 of the organic EL device contains at least one hole-transporting compound, such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural formula (A).

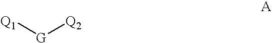

wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B):

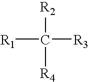

where

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula (C):

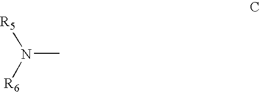

wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by formula (C), linked through an arylene group. Useful tetraaryldiamines include those represented by formula (D).

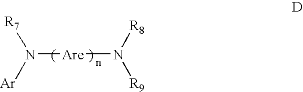

wherein

each Are is an independently selected arylene group, such as a phenylene or anthracene moiety,

n is an integer of from 1 to 4, and

Ar, R₇, R₈, and R₉ are independently selected aryl groups.

In a typical embodiment, at least one of Ar, R₇, R₈, and R₉ is a polycyclic fused ring structure, e.g., a naphthalene

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy groups, and halogen such as fluoride, chloride, and bromide. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single or a mixture of aromatic tertiary amine compounds. Specifically, one may employ a triarylamine, such as a triarylamine satisfying the formula (B), in combination with a tetraaryldiamine, such as indicated by formula (D). When a triarylamine is employed in combination with a tetraaryldiamine, the latter is positioned as a layer interposed between the triarylamine and the electron injecting and transporting layer. Illustrative of useful aromatic tertiary amines are the following:
1,1-Bis(4-di-p-tolylaminophenyl)cyclohexane (TAPC)
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolylamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl
4,4′-Bis[N-(1-naphthyl)-N-(2-naphthyl)amino]biphenyl
4,4″-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenylamino]triphenylamine

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

The light-emitting layer has been described previously. The device may have more than one light-emitting layer. As more fully described in U.S. Pat. Nos. 4,769,292 and 5,935,721, the additional light-emitting layer (LEL) of the organic EL element may include a luminescent fluorescent or phosphorescent material where electroluminescence is produced as a result of electron-hole pair recombination in this region. The light-emitting layer can be comprised of a single material, but more commonly consists of a host material doped with a guest emitting material or materials where light emission comes primarily from the emitting materials and can be of any color. The host materials in the light-emitting layer can be an electron-transporting material, as defined below, a hole-transporting material, as defined above, or another material or combination of materials that support hole-electron recombination. The emitting material is usually chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the band gap of the dopant is smaller than that of the host material. For phosphorescent emitters it is also important that the host triplet energy level of the host be high enough to enable energy transfer from host to emitting material.

Host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives (Formula E) constitute one class of useful host compounds capable of supporting electroluminescence, and are particularly suitable for light emission of wavelengths longer than 500 nm, e.g., green, yellow, orange, and red. 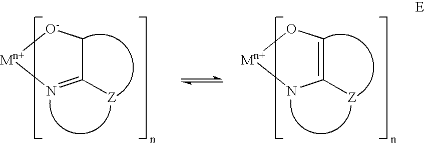
wherein

M represents a metal;

n is an integer of from 1 to 4; and

Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III); Alq]
CO-2: Magnesium bisoxine [alias, bis(8-quinolinolato)magnesium(II)]
CO-3: Bis[benzo {f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

As described previously, derivatives of anthracene (Formula F) constitute one class of useful host materials capable of supporting electroluminescence, and are particularly suitable for light emission of wavelengths longer than 400 nm, e.g., blue, green, yellow, orange or red. Asymmetric anthracene derivatives as disclosed in U.S. Pat. No. 6,465,115 and WO 2004/018587 are also useful hosts.

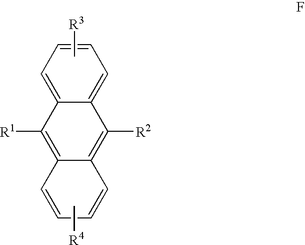

wherein: R¹ and R² represent independently selected aryl groups, such as naphthyl, phenyl, biphenyl, triphenyl, anthracene.

R³ and R⁴ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine, or cyano.

A useful class of anthracenes are derivatives of 9,10-di-(2-naphthyl)anthracene (Formula G). 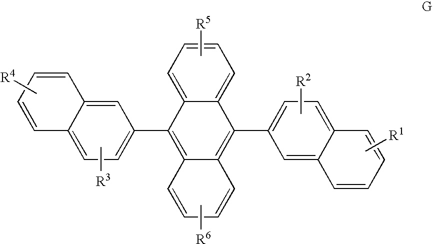
wherein: R¹, R², R³, R⁴, R⁵, and R⁶ represent one or more substituents on each ring where each substituent is individually selected from the following groups:
Group 1: hydrogen, or alkyl of from 1 to 24 carbon atoms;
Group 2: aryl or substituted aryl of from 5 to 20 carbon atoms;
Group 3: carbon atoms from 4 to 24 necessary to complete a fused aromatic ring of anthracenyl; pyrenyl, or perylenyl;
Group 4: heteroaryl or substituted heteroaryl of from 5 to 24 carbon atoms as necessary to complete a fused heteroaromatic ring of furyl, thienyl, pyridyl, quinolinyl or other heterocyclic systems;
Group 5: alkoxylamino, alkylamino, or arylamino of from 1 to 24 carbon atoms; and
Group 6: fluorine or cyano.

Illustrative examples of anthracene materials for use in a light-emitting layer include: 2-(4-methylphenyl)-9,10-di-(2-naphthyl)-anthracene; 9-(2-naphthyl)-10-(1,1′-biphenyl)-anthracene; 9,10-bis[4-(2,2-diphenylethenyl)phenyl]-anthracene, as well as the following listed compounds.

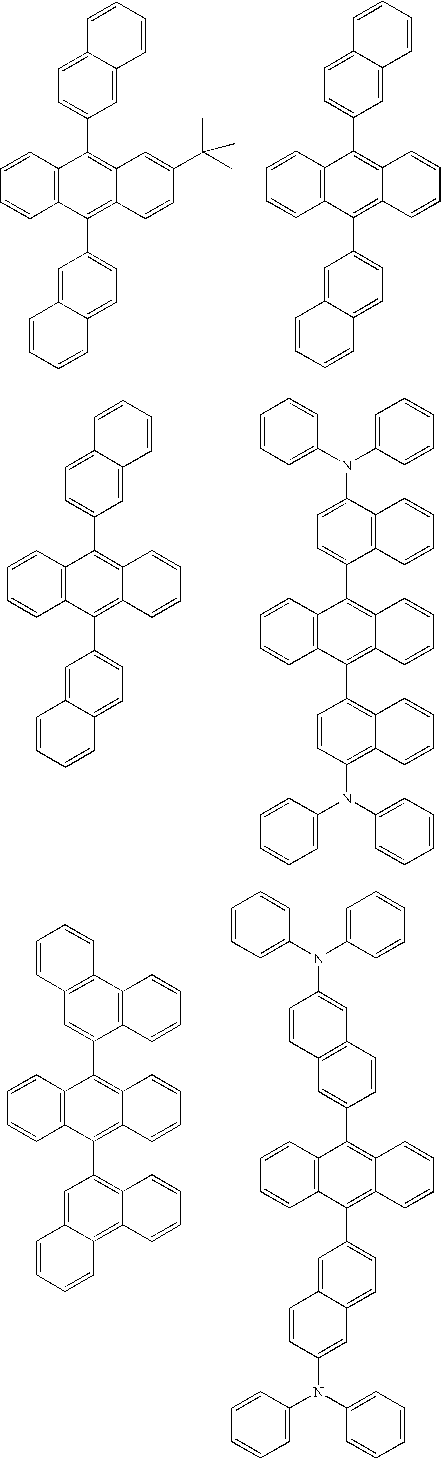

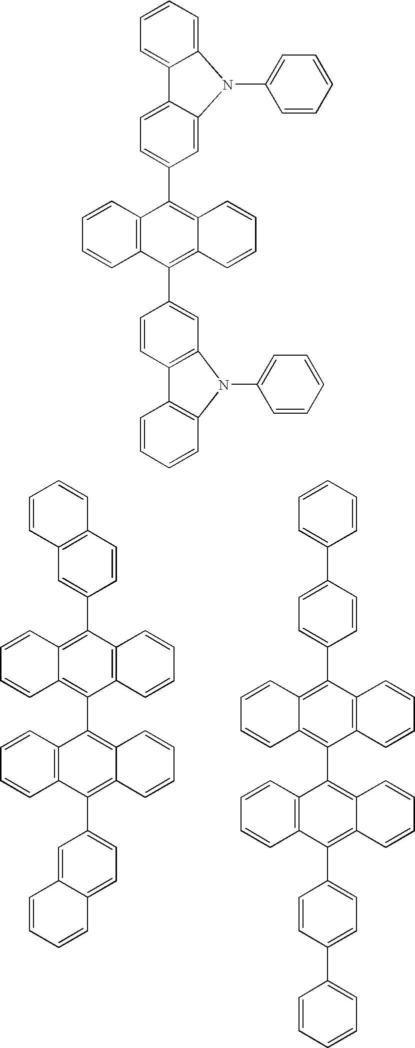

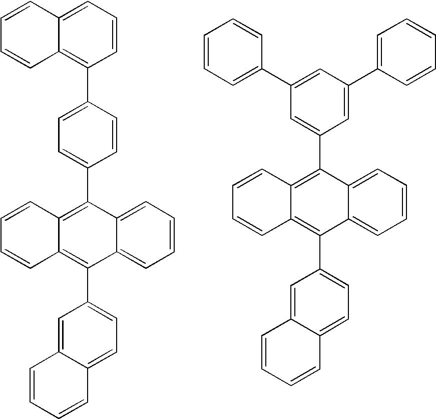

Benzazole derivatives (Formula H) constitute another class of useful host materials capable of supporting electroluminescence, and are particularly suitable for light emission of wavelengths longer than 400 nm, e.g., blue, green, yellow, orange or red. 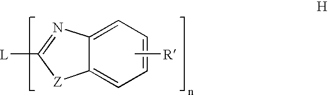
Where:

n is an integer of 3 to 8;

Z is O, NR or S; and

R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring;

L is a linkage unit consisting of alkyl, aryl, substituted alkyl, or substituted aryl, which conjugately or unconjugately connects the multiple benzazoles together. An example of a useful benzazole is 2,2′,2″-(1,3,5-phenylene)tris[1-phenyl-1H-benzimidazole].

Distyrylarylene derivatives are also useful hosts, as described in U.S. Pat. No. 5,121,029. Carbazole derivatives are particularly useful hosts for phosphorescent emitters.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds. Illustrative examples of useful materials include, but are not limited to, the following:

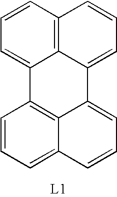

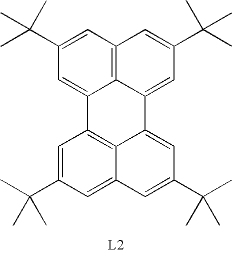

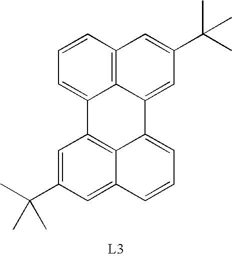

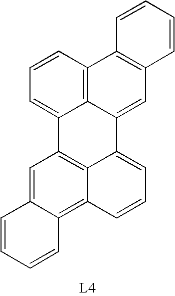

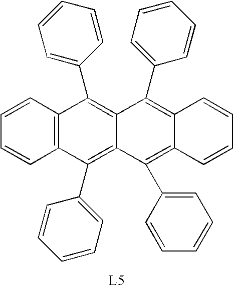

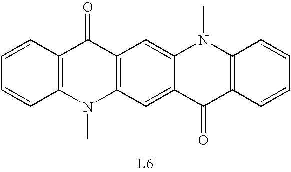

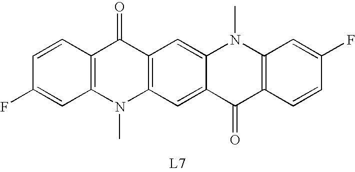

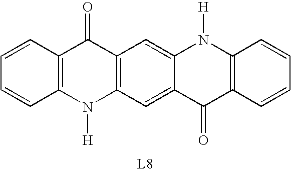

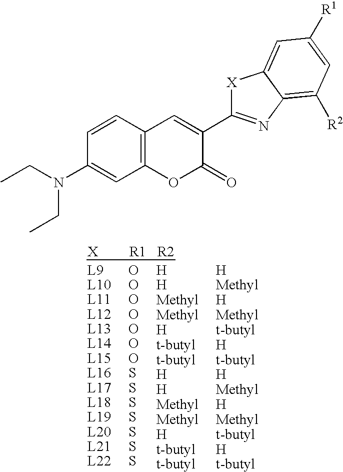

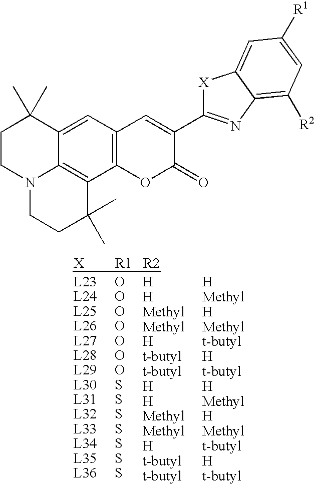

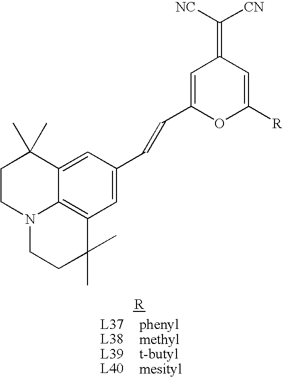

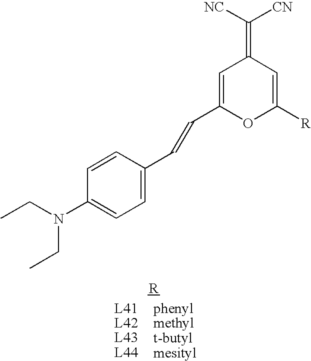

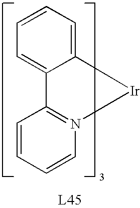

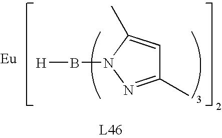

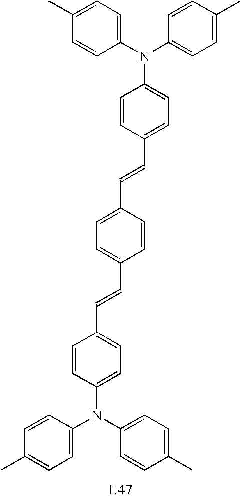

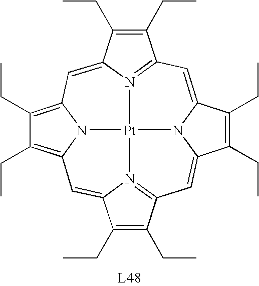

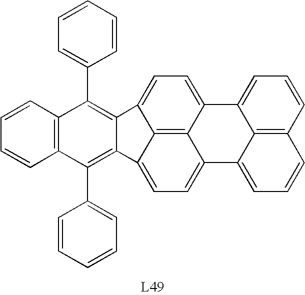

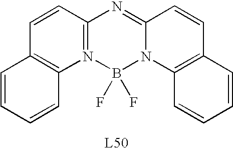

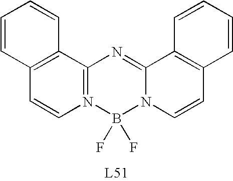

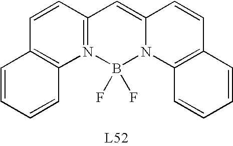

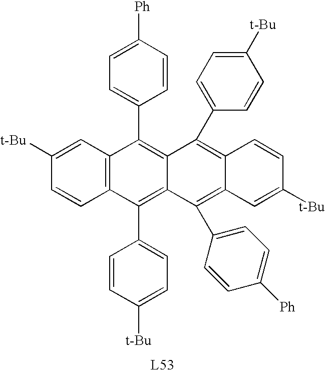

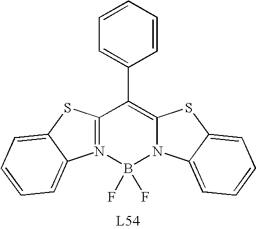

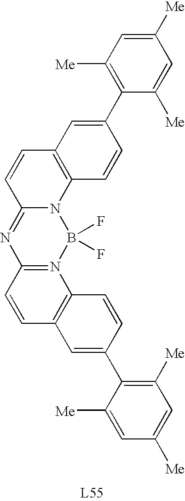

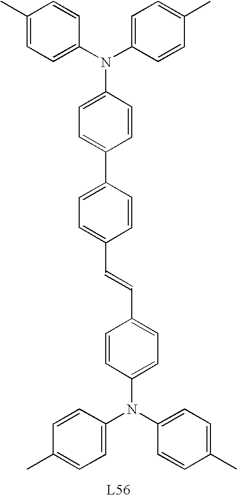

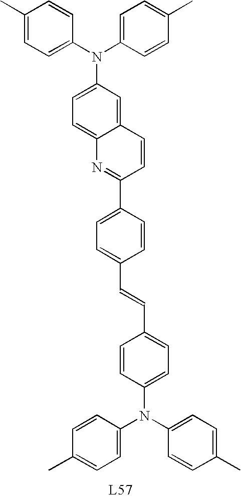

Electron-Transporting Layer (ETL)

Preferred thin film-forming materials for use in forming the electron-transporting layer of the organic EL devices of this invention are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural formula (E), previously described. Other electron-transporting materials include various butadiene derivatives as disclosed in U.S. Pat. No. 4,356,429 and various heterocyclic optical brighteners as described in U.S. Pat. No. 4,539,507. Benzazoles satisfying structural formula (H) are also useful electron transporting materials. Triazines are also known to be useful as electron transporting materials. Further useful materials are silacyclopentadiene derivatives described in EP 1,480,280; EP 1,478,032; and EP 1,469,533. Substituted 1,10-phenanthroline compounds (including those listed below) such as are disclosed in JP2003-115387; JP2004-311184; JP2001-267080; and WO2002-043449. Pyridine derivatives are described in JP2004-200162 as useful electron transporting materials. 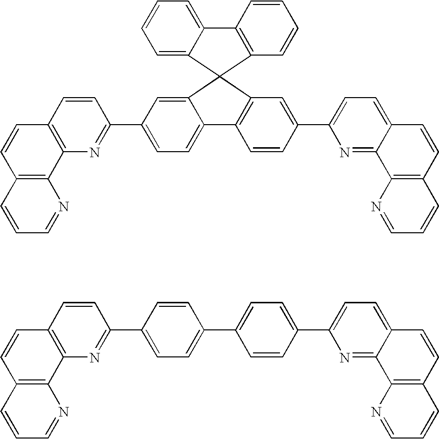
Electron-Injecting Layer (EIL)

Electron-injecting layers, when present, include those described in U.S. Pat. Nos. 5,608,287; 5,776,622; 5,776,623; 6,137,223; and 6,140,763, U.S. Pat. No. 6,914,269 the disclosures of which are incorporated herein by reference. An electron-injecting layer generally consists of a material having a work function less than 4.0 eV. A thin-film containing low work-function alkaline metals or alkaline earth metals, such as Li, Cs, Ca, Mg can be employed. In addition, an organic material doped with these low work-function metals can also be used effectively as the electron-injecting layer. Examples are Li- or Cs-doped Alq. In one suitable embodiment the electron-injecting layer includes LiF. In practice, the electron-injecting layer is often a thin layer deposited to a suitable thickness in a range of 0.1-3.0 nm.

Cathode

When light emission is viewed solely through the anode, the cathode used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising the cathode and a thin electron-injection layer (EIL) in contact with an organic layer (e.g., an electron transporting layer (ETL)) which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of A1 as described in U.S. Pat. No. 5,677,572. Other useful cathode material sets include, but are not limited to, those disclosed in U.S. Pat. Nos. 5,059,861; 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Other Useful Organic Layers and Device Architecture

In some instances, layers 109 and 111 can optionally be collapsed into a single layer that serves the function of supporting both light emission and electron transportation. It also known in the art that emitting materials may be included in the hole-transporting layer, which may serve as a host. Multiple materials may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, US 2002/0025419, EP 1 182 244, U.S. Pat. No. 5,683,823, U.S. Pat. No. 5,503,910, U.S. Pat. No. 5,405,709, and U.S. Pat. No. 5,283,182 and may be equipped with a suitable filter arrangement to produce a color emission.

Additional layers such as electron or hole-blocking layers as taught in the art may be employed in devices of this invention. Hole-blocking layers may be used between the light emitting layer and the electron transporting layer. Electron-blocking layers may be used between the hole-transporting layer and the light emitting layer. These layers are commonly used to improve the efficiency of emission, for example, as in US 2002/0015859.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited by any means suitable for the form of the organic materials. In the case of small molecules, they are conveniently deposited through sublimation, but can be deposited by other means such as from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,688,551, U.S. Pat. No. 5,851,709 and U.S. Pat. No. 6,066,357) and inkjet method (U.S. Pat. No. 6,066,357).

One preferred method for depositing the materials of the present invention is described in US 2004/0255857 and U.S. Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned patent applications: U.S. Ser. No. 10/784,585; U.S. Ser. No. 10/805,980; U.S. Ser. No. 10/945,940; U.S. Ser. No. 10/945,941; U.S. Ser. No. 11/050,924; and U.S. Ser. No. 11/050,934. Using this second method, each material may be evaporated using different source evaporators or the solid materials may be mixed prior to evaporation using the same source evaporator.

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

Embodiments of the invention may provide advantageous features such as higher luminous yield, lower drive voltage, and higher power efficiency, longer operating lifetimes or ease of manufacture. Embodiments of devices useful in the invention can provide a wide range of hues including those useful in the emission of white light (directly or through filters to provide multicolor displays). Embodiments of the invention can also provide an area lighting device.

The invention and its advantages are further illustrated by the specific examples that follow. The term “percentage” or “percent” and the symbol “%” indicate the volume percent (or a thickness ratio as measured on a thin film thickness monitor) of a particular first or second compound of the total material in the layer of the invention and other components of the devices. If more than one second compound is present, the total volume of the second compounds can also be expressed as a percentage of the total material in the layer of the invention.

### EXAMPLE 1

### Synthesis of Inv-1

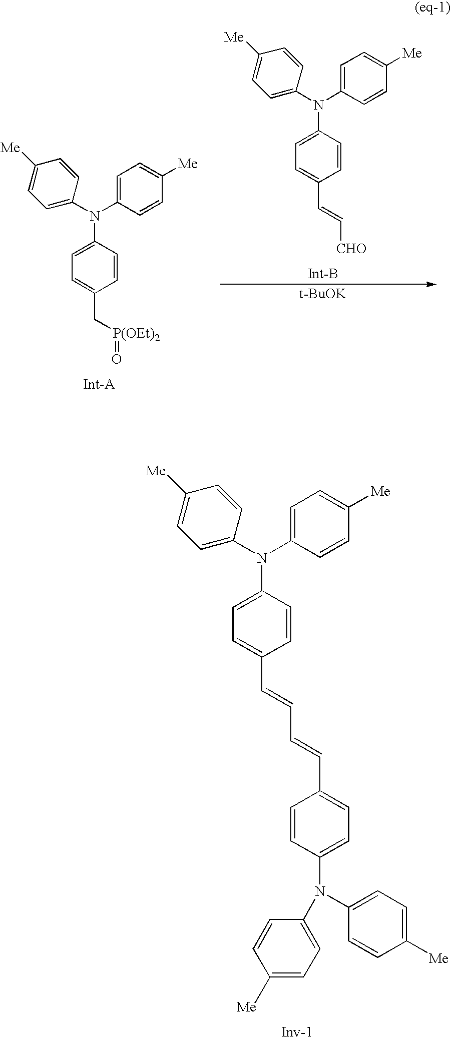

Inv-1 was prepared according to equation 1; the preparation of a similar material is described in US 2003/105070. A mixture of Int-A (1.27 g, 3 mmol) and Int-B (0.987 g, 3 mmol) in 10 mL of a mixture of tetrahydrofuran and dimethylforamide (1:1) was added to potassium t-butoxide (0.320 g, 3.3 mmol) in 5 mL of tetrahydrofuran which had been cooled to 0° C. After addition, the temperature was allowed to increase to room temperature while stirring the mixture for 1 h. Water was added and the product was extracted, dried, and evaporated to a solid. The crude product was purified by column chromatography (silica gel, heptane/ethyl acetate eluent) to afford 0.3 g of Inv-1, which sublimed at 240° C.

### EXAMPLE 2

### Preparation of Devices 1-1 through 1-6

A series of EL devices (1-1 through 1-6) were constructed in the following manner.
1. A glass substrate coated with a 25 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
3. Next a layer of hole-transporting material 4,4′-Bis[N-(1-naphthyl)-N-phenylamino]biphenyl (NPB) was deposited to a thickness of 75 nm.
4. A 20 nm light-emitting layer (LEL) corresponding to 10-(4-biphenyl)-9-(2-naphthyl)anthracene (H-2) and light-emitting material, Inv-1 or L-2 at the level shown in Table 1 was then deposited.
5. A 35 nm electron-transporting layer (ETL) of tris(8-quinolinolato)aluminum (III) (Alq) was vacuum-deposited over the LEL.
6. 0.5 nm layer of lithium fluoride was vacuum deposited onto the ETL, followed by a 150 nm layer of aluminum, to form a cathode layer.

The above sequence completes the deposition of the EL device. The device is then hermetically packaged in a dry glove box for protection against ambient environment.

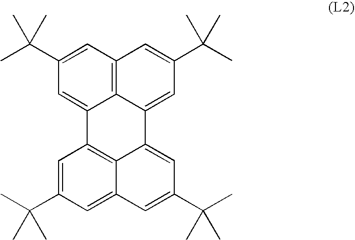

The devices were tested for luminous efficiency and color at an operating current of 20 mA/cm² and the results are reported in Table 1 in the form of luminous yield (cd/A) and efficiency (w/A), where device efficiency is the radiant flux (in watts) produced by the device per amp of input current, where radiant flux is the light energy produced by the device per unit time. Light intensity is measured perpendicular to the device surface, and it is assumed that the angular profile is Lambertian. The color of light produced by the devices is reported in 1931 CIE (Commission Internationale de L'Eclairage) coordinates.

TABLE 1
Evaluation results for Devices 1-1 through 1-6.

| | | | | | | | Luminous | |
|---|---|---|---|---|---|---|---|---|
| | | | Emitter Level | | | Voltage | Yield | Efficiency |
| | Example | Emitter | (%) | CIEx | CIEy | (V) | (cd/A) | (W/A) |
| 1-1 | Comparative | — | 0 | 0.174 | 0.143 | 6.87 | 1.51 | 0.032 |
| 1-2 | Inventive | Inv-1 | 2 | 0.161 | 0.297 | 6.59 | 6.71 | 0.085 |
| 1-3 | Inventive | Inv-1 | 4 | 0.167 | 0.333 | 6.92 | 8.11 | 0.095 |
| 1-4 | Inventive | Inv-1 | 6 | 0.174 | 0.360 | 6.43 | 8.36 | 0.093 |
| 1-5 | Inventive | Inv-1 | 8 | 0.182 | 0.380 | 6.39 | 8.39 | 0.089 |
| 1-6 | Comparative | L-2 | 1.5 | 0.147 | 0.192 | 6.37 | 3.32 | 0.059 |

It can be seen from Table 1 that the inventive material affords a blue-green emission. The inventive material also offers higher luminance yield and efficiency relative to the comparison material L-2, which emits blue light.

### EXAMPLE 3

### Preparation of Devices 2-1 through 2-6

A series of EL devices (1-1 through 1-6) were constructed in the following manner.
1. A glass substrate coated with an 25 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
7. Next a layer of hole-transporting material 4,4′-Bis[N-(1-naphthyl)-N-phenylamino]biphenyl (NPB) was deposited to a thickness of 75 nm.
8. A 20 nm light-emitting layer (LEL) corresponding to 10-(4-biphenyl)-9-(2-naphthyl)anthracene (H-2) and light-emitting material Inv-1 or L-47 at the level shown in Table 2 was then deposited.
9. A 35 nm electron-transporting layer (ETL) of tris(8-quinolinolato)aluminum (III) (Alq) was vacuum-deposited over the LEL.
10. 0.5 nm layer of lithium fluoride was vacuum deposited onto the ETL, followed by a 150 nm layer of aluminum, to form a cathode layer.

The above sequence completes the deposition of the EL device. The device is then hermetically packaged in a dry glove box for protection against ambient environment.

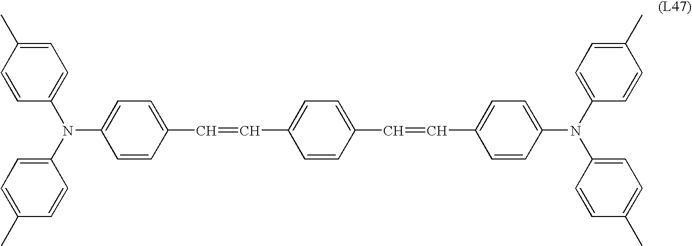

The devices were tested for luminous efficiency and color at an operating current of 20 mA/cm² and the results are reported in Table 2 in the form of luminous yield (cd/A) and efficiency (w/A). The color of light produced by the devices is reported in 1931 CIE coordinates.

TABLE 2
Evaluation results for Devices 2-1 through 2-6.

| | | | | | | | Luminous | |
|---|---|---|---|---|---|---|---|---|
| | | | Emitter Level | | | Voltage | Yield | Efficiency |
| | Example | Emitter | (%) | CIEx | CIEy | (V) | (cd/A) | (W/A) |
| 2-1 | Comparative | — | 0 | 0.169 | 0.126 | 6.86 | 1.44 | 0.035 |
| 2-2 | Inventive | Inv-1 | 2 | 0.160 | 0.235 | 6.79 | 4.05 | 0.061 |
| 2-3 | Inventive | Inv-1 | 4 | 0.159 | 0.291 | 6.96 | 7.22 | 0.094 |
| 2-4 | Inventive | Inv-1 | 6 | 0.163 | 0.326 | 7.15 | 8.68 | 0.104 |
| 2-5 | Inventive | Inv-1 | 8 | 0.168 | 0.343 | 6.94 | 8.88 | 0.103 |
| 2-6 | Comparative | L-47 | 3 | 0.160 | 0.340 | 6.97 | 8.65 | 0.103 |

It can be seen from Table 2 that the inventive material affords a blue-green emission. The inventive material also offers similar or higher luminance yield and efficiency relative to the comparison material L-47.

### EXAMPLE 4

### Preparation of Devices 3-1 through 3-6

A series of EL devices (3-1 through 3-6) were constructed in the following manner.
1. A glass substrate coated with a 25 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
3. Next a layer of hole-transporting material 4,4′-Bis[N-(1-naphthyl)-N-phenylamino]biphenyl (NPB) was deposited to a thickness of 75 nm.
4. A 40 nm light-emitting layer (LEL) was then deposited corresponding to 10-(4-biphenyl)-9-(2-naphthyl)anthracene (H-2) or TAZ (C-1), see Table 3, and including light-emitting material Inv-1 at the level shown in Table 3.
5. A 35 nm electron-transporting layer (ETL) of tris(8-quinolinolato)aluminum (III) (Alq) was vacuum-deposited over the LEL.
6. 0.5 nm layer of lithium fluoride was vacuum deposited onto the ETL, followed by a 150 nm layer of aluminum, to form a cathode layer.

The above sequence completes the deposition of the EL device. The device is then hermetically packaged in a dry glove box for protection against ambient environment.

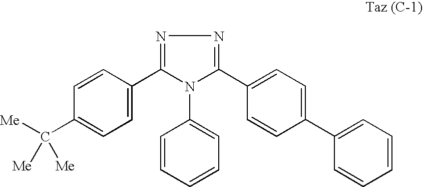

The devices were tested for luminous efficiency and color at an operating current of 20 mA/cm² and the results are reported in Table 3 in the form of luminous yield (cd/A) and efficiency (w/A). The color of light produced by the devices is reported in 1931 CIE coordinates.

TABLE 3
Evaluation results for Devices 3-1 through 3-6.

| | | | Inv-1 | | | | Luminous | |
|---|---|---|---|---|---|---|---|---|
| | | | Level | | | Voltage | Yield | Efficiency |
| Device | Example | Host | (%) | CIEx | CIEy | (V) | (cd/A) | (W/A) |
| 3-1 | Inventive | H-2 | 4 | 0.169 | 0.359 | 9.2 | 9.0 | 0.101 |
| 3-2 | Inventive | H-2 | 6 | 0.173 | 0.373 | 8.8 | 9.7 | 0.105 |
| 3-3 | Inventive | H-2 | 8 | 0.177 | 0.379 | 8.4 | 10.1 | 0.108 |
| 3-4 | Comparative | C-1 | 4 | 0.151 | 0.226 | 8.9 | 2.1 | 0.032 |
| 3-5 | Comparative | C-1 | 6 | 0.154 | 0.280 | 10.1 | 2.7 | 0.036 |
| 3-6 | Comparative | C-1 | 8 | 0.156 | 0.295 | 8.5 | 2.4 | 0.031 |

It is clear from Table 3 that the combination of Inv-1 and H-2 affords very high luminance relative to the Inv-1/C-1 combination. In addition, the devices that contain Inv-1/H-2 emit blue-green light whereas the Inv-1/C-1 devices produce a more blue emission. Thus the material H-2, which contains an anthracene moiety, is a superior host for Inv-1 compared to TAZ (C-1), which does not include an anthracene nucleus.

The entire contents of the patents and other publications referred to in this specification are incorporated herein by reference. The invention has been described in detail with particular reference to certain preferred embodiments thereof, but it will be understood that variations and modifications can be effected within the spirit and scope of the invention.

### PARTS LIST

101 Substrate
103 Anode
105 Hole-Injecting layer (HIL)
107 Hole-Transporting Layer (HTL)
109 Light-Emitting layer (LEL)
111 Electron-Transporting layer (ETL)
112 Electron-Injecting Layer (EIL)
113 Cathode
150 Power Source
160 Conductor

1. An OLED device comprising a cathode, an anode and a light-emitting layer therebetween, wherein the light-emitting layer comprises a host containing an anthracene nucleus and a light-emitting material comprising a 1,3-butadiene nucleus, wherein the butadiene nucleus is substituted in the 1 and 4 positions with independently selected aromatic groups, and wherein at least one of said aromatic groups is further substituted with an amino group, and wherein said amino group is further substituted with two independently selected aryl or heteroaryl groups.

2. The device of claim 1 wherein the butadiene nucleus is substituted in the 1 and 4 positions with independently selected aromatic groups, and wherein each of said aromatic groups is further substituted with an amino group, and wherein each of said amino groups is further substituted with two independently selected aryl or heteroaryl groups.

3. The device of claim 1 wherein the host material is an anthracene group substituted in the 9- and 10-positions with two independently selected aromatic groups.

4. The device of claim 1 wherein the light-emitting material is present at a level of 2% to 8% of the layer by volume.

5. The device of claim 1 wherein light-emitting material is represented by Formula (1): 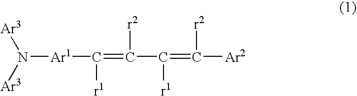
wherein:
Ar¹ and Ar² represent independently selected aromatic groups;
each Ar³ may be the same or different and each represents an independently selected aromatic group, provided the two Ar³ groups may combine to form a ring group;
each r¹ may be the same or different and each represents hydrogen or an independently selected substituent; and
each r² may be the same or different and each represents hydrogen or an independently selected substituent;

6. The device of claim 5 wherein at least one r¹ and at least one r² represents hydrogen.

7. The device of claim 5 wherein each r¹ and each r² represents hydrogen.

8. The device of claim 5 wherein Ar² is further substituted with a —N(Ar⁴)(Ar⁴) group, wherein each Ar⁴ may be the same or different and each represents an independently selected aromatic group, provided the two Ar⁴ groups may combine to form a ring group.

9. The device of claim 5 wherein each Ar¹, Ar², and Ar³ represents an independently selected carbocyclic aromatic group.

10. The device of claim 5 wherein Ar¹ represents a biphenylene group.

11. The device of claim 1 wherein light-emitting material is represented by Formula (2): 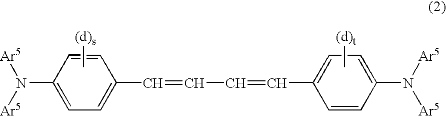
wherein:
each Ar⁵ may be the same or different and each represents an independently selected aromatic group, provided two adjacent Ar⁵ groups may combine to form a ring group;
each d represents an independently selected substituent, provided two adjacent d groups may combine to form a ring group; and
s and t are independently 0-4.

12. The device of claim 11 wherein s and t are 0.

13. The device of claim 1 wherein the host material is represented by Formula (3): 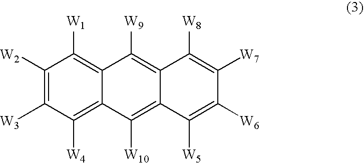
wherein:
W₁-W₁₀ independently represent hydrogen or an independently selected substituent, provided that two adjacent substituents can combine to form rings.

14. The device of claim 13 wherein W₉ and W₁₀ represent independently selected naphthyl groups or biphenyl groups.

15. The device of claim 13 wherein at least one of W₉ and W₁₀ represents an anthracene group.

16. The device of claim 13 wherein W₉ and W₁₀ represent independently selected naphthyl groups or biphenyl groups and W₇ represents an aromatic group.

17. The device of claim 1 wherein the light-emitting material emits blue or blue-green light.

18. The device of claim 1 wherein a second light emitting layer is present.

19. The device of claim 18 wherein the second light emitting layer emits yellow light.

20. The device of claim 1 wherein white light is produced either directly or by using filters.
